(19) United States
(12) Patent Application Publication
(10) Pub. No.: US 2009/0288948 A1
(43) Pub. Date: Nov. 26, 2009

(54) PHYSICAL VAPOR DEPOSITION APPARATUS

(75) Inventor: SHIH-CHE CHIEN, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/463,419

(22) Filed: May 10, 2009

(30) Foreign Application Priority Data
May 23, 2008 (CN) 200810301734.8

(51) Int. Cl. C23C 14/34

(52) U.S. Cl. 204/298.03

(57) ABSTRACT

A physical vapor deposition apparatus includes a vacuum chamber, a particles producing means, a substrate stand, a correction plate, and an ion source disposed in the vacuum chamber. The physical vapor deposition apparatus further includes a strain gauge adhered on the correction plate for detecting deforming of the correction plate, a controlling circuit electrically coupled to the strain gauge, and an alarm electrically connected to the controlling circuit. The controlling circuit is configured for controlling the alarm to produce an alert signal when the deforming of the correction plate exceeds a predetermined degree.

### BACKGROUND

1. Technical Field

The present invention relates to a physical vapor deposition apparatus, and particularly to a physical vapor deposition apparatus having correction plates.

2. Description of Related Art

Currently, optical coatings are widely employed in optical lenses. For mass production, optical coatings are deposited in physical vapor deposition (PVD) apparatuses. Generally, PVD includes an evaporating and a sputtering process. The evaporating and sputtering process utilize similar apparatuses, but the processes of producing micro particles to depositing coatings are different. An evaporating apparatus generally includes a vacuum chamber, a heater and an umbrella like substrate stand disposed in the vacuum chamber. The heater is positioned opposite to the substrate stand, and is used to heat and evaporate target material. To obtain an optical coating having a uniform thickness, the substrate stand is rotated during an evaporating process. It is understood that moving velocities of different positions of the substrate stand are still different, and therefore uniform optical coating cannot be obtained by solely rotating the substrate stand. Correction plates are developed to overcome this problem. Correction plates can be disposed between the target material and the substrate stand to mask portions of the substrate stand. However, after a long period of usage, the deformations of the correction plates may lead to non-uniform optical coatings. In this condition, the correction plates need to be replaced with new ones.

What is needed, therefore, is a PVD apparatus that to alleviate the aforementioned problem.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of embodiments. Moreover, in the drawings, like reference numerals designate corresponding parts throughout the different views.

FIG. 1 is a schematic view illustrating a PVD apparatus in accordance with an embodiment, which having a strain gauge, a controlling circuit, and an alarm.

FIG. 2 is a block diagram showing relations of the strain gauge, the controlling circuit and the alarm of FIG. 1.

FIG. 3 is circuit diagram of one embodiment of the controlling circuit.

### DETAILED DESCRIPTION

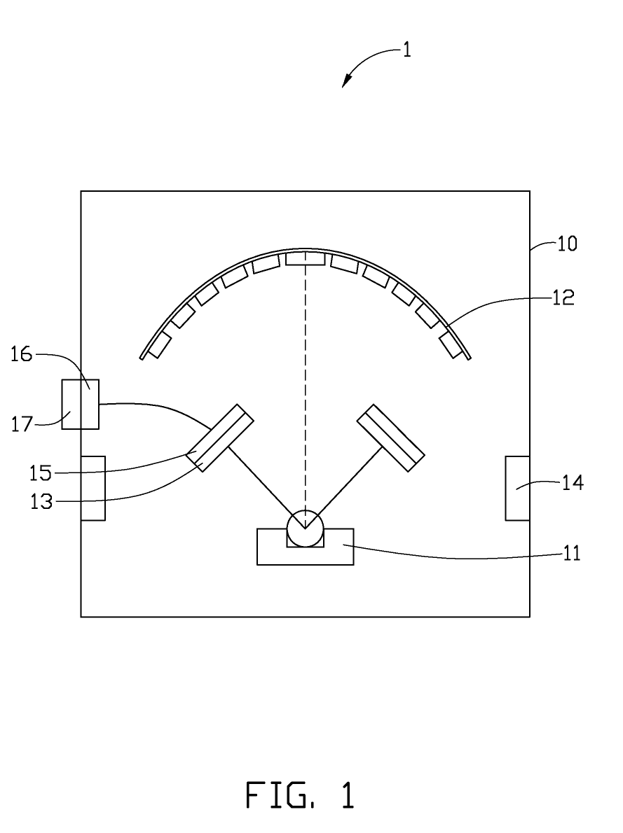

Referring to FIG. 1, a PVD apparatus 1 in accordance with an embodiment includes a vacuum chamber 10, a particles producing means 11, a substrate stand 12, a correction plate 13, an ion source 14, a strain gauge 15, a controlling circuit 16, and an alarm 17.

The particles producing means 11, the substrate stand 12, the correction plate 13, and the ion source 14 are disposed in the vacuum chamber 10. Examples of the particles producing means 11 include an electron-beam heater, a heating coil, or a bombarding ion source. To perform an evaporating process, the electron-beam heater or the heating coil can be employed to heat a target material received in a container (e.g., a crucible) to produce micro particles. To perform a sputtering process, the bombarding ion source can be used to generate an ion beam to bombard the target material in the container to form plasma.

The substrate stand 12 has an umbrella like shape, and the target material is disposed at a position at which substrates 121 on the substrate stand 12 are apart from the target material at substantially same distances. The correction plate 13 is disposed between the particles producing means 11 (particularly an edge portion of the particles producing means 11), and the substrate stand 12. It is understood that the number and the shape of the correction plate 13 is not limited and can be varied according to practical design requirements. Each correction plate 13 can block a portion of the particles generated in the particles producing means 11 thereby adjusting a concentration of the particles on surfaces of different substrates.

The ion source 14 is configured for generating ion beams to bombard optical coatings formed on the substrates to improve performance of the optical coatings. In this embodiment, the ion source 14 is fixed on an inner side wall of the vacuum chamber 10. The strain gauge 15 (an insulating flexible backing which supports a metallic foil pattern, in one example) is adhered on the correction plate 13 by a suitable adhesive, such as cyanoacrylate. It is understood that the ion beams from the ion source 14 also bombard the correction plates 13. After a long period of bombardment, the correction plates 13 deforms. As the correction plate 13 is deformed, the strain gauge 15 is deformed, causing its electrical resistance to change.

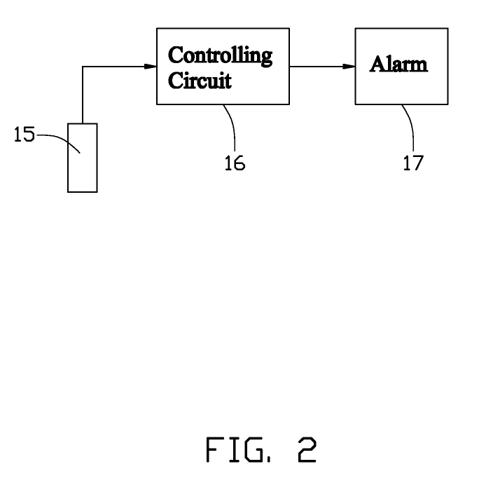

Referring to FIG. 2, the strain gauge 15 and the alarm 17 are both electrically connected to the controlling circuit 16. The controlling circuit 16 monitors electrical resistance of the strain gauge 15, determines whether the deformation of the correction plate 13 exceeds a predetermined degree, and controls the alarm 17 to output corresponding signals.

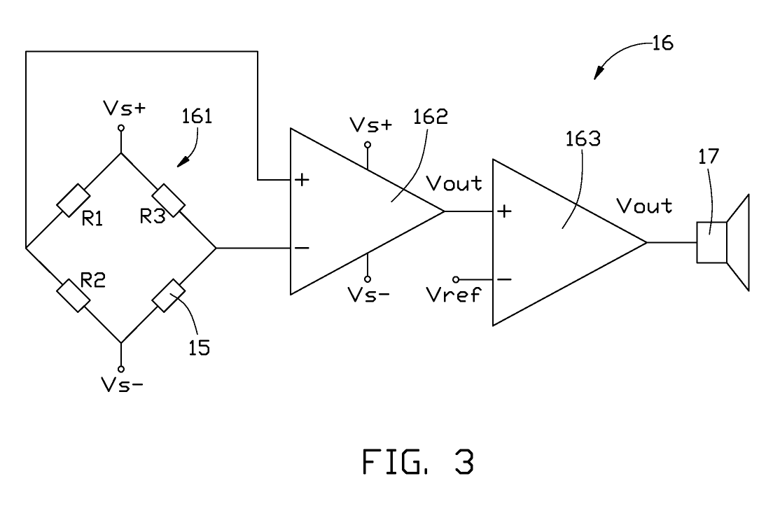

FIG. 3 illustrates a circuit diagram of one embodiment of the controlling circuit 16. The controlling circuit 16 includes resistors R₁, R₂, R₃ of a known resistance, an operational amplifier (op-amp) 162, and a voltage comparator 163. The op-amp 162 includes a non-inverting input pin (+), an inverting input pin (−), an output pin (Vₒᵤₜ), a positive power supply pin (Vₛ₊), and a negative power supply pin (Vₛ₋). The voltage comparator 163 includes two input pins (+/−) and an output pin Vₒᵤₜ.

The resistors R₁, R₂, R₃, and the strain gauge 15 are electrically connected to constitute a Wheatstone bridge 161, and two output pins of the Wheatstone bridge 161 are connected to non-inverting input pin and inverting input pin (−) of the operation amplifier 162, respectively. The output pin of the op-amp 162 is connected to one of the two input pins of the voltage comparator 163, and another input pin of the voltage comparator 163 is connected to a reference voltage V_{ref}. The output pin of the voltage comparator 163 is connected to the alarm 17.

As the correction plate 13 is deformed, the resistance of the strain gauge 15 varies, and the output voltage of the Wheatstone bridge 161 also varies. The output voltage of the Wheatstone bridge 161 is amplified by the op-amp 162 and sent to the voltage comparator 163. The voltage comparator 163 compares the voltage with the reference voltage V_{ref}. Because the output voltage of the Wheatstone bridge 161 is in proportion with the deformation of the correction plate 13, therefore, by comparing the output voltage of the op-amp 162 with the reference voltage V_{ref}, the controlling circuit 16 will know whether deformation of the correction plate 13 exceeds a predetermined degree (indicated by the reference voltage V_{ref}). When the deformation of the correction plate 13 exceeds the predetermined degree, the controlling circuit 16 controls the alarm to produce an alarm signal (for example, sound alert or light alert). As such, the PVD apparatus 1 can immediately notify the user to replace the correction plate 13, and a quality of optical coatings deposited using the PVD apparatus 1 is improved.

In this embodiment, the voltage comparator 163 is an operational amplifier type voltage comparator. However, the voltage comparator 163 can also be replaced with other integrated chips such as dedicated voltage comparator chips. In this condition, additional controlling unit can be added between the integrated chips and the alarm 17.

While certain embodiments have been described and exemplified above, various other embodiments will be apparent to those skilled in the art from the foregoing disclosure. The present invention is not limited to the particular embodiments described and exemplified but is capable of considerable variation and modification without departure from the scope of the appended claims.

What is claimed is:

1. A physical vapor deposition apparatus for depositing a coating from a plurality of particles, comprising:
a vacuum chamber;
a particles producing means, a substrate stand, a correction plate, and an ion source disposed in the vacuum chamber, the particles producing means configured for providing the plurality of particles, the substrate stand configured for holding a plurality of substrates thereon, the correction plate being disposed between the substrate stand and the particles producing means and the ion source, the ion source configured for producing an ion beam to bombard the coating;
a strain gauge adhered on the correction plate to detect deformation of the correction plate;
a controlling circuit electrically coupled to the strain gauge; and
an alarm electrically connected to the controlling circuit, the controlling circuit configured for controlling the alarm to produce an alert signal when the deformation of the correction plate exceeds a predetermined degree.

2. The physical vapor deposition apparatus as claimed in claim 1, wherein the controlling circuit comprises three resistors of a known resistance, the three resistors and the strain gauge constituting a wheatstone bridge for producing an output voltage.

3. The physical vapor deposition apparatus as claimed in claim 2, wherein the controlling circuit comprises an operational amplifier electrically coupled to the Wheatstone bridge, the operational amplifier configured for amplifying the output voltage of the Wheatstone bridge.

4. The physical vapor deposition apparatus as claimed in claim 2, wherein the controlling circuit comprises an integrated circuit chip electrically coupled to the Wheatstone bridge, the integrated circuit configured for comparing the output voltage with a reference voltage.

5. The physical vapor deposition apparatus as claimed in claim 4, wherein integrated circuit chip is an operational amplifier type voltage comparator.

6. The physical vapor deposition apparatus as claimed in claim 1, wherein the particles producing means comprises a container and a heater.

7. The physical vapor deposition apparatus as claimed in claim 1, wherein the particles producing means comprises a container to receive a target material and a bombarding ion source to produce ion beams to bombard the target material in the container.
